(19) United States
(12) Patent Application Publication
(10) Pub. No.: US 2007/0133176 A1
(43) Pub. Date: Jun. 14, 2007

(54) Heat dissipating element for a memory

(76) Inventor: Ruei-An Lo, Taipei (TW)

Correspondence Address: Ruei-An Lo, P.O. Box No. 6-57, Junghe, Taipei, 235, TW

(21) Appl. No.: 11/296,445

(22) Filed: Dec. 8, 2005

(51) Int. Cl. H05K 7/20

(52) U.S. Cl. 361/704

(57) ABSTRACT

A heat dissipating element for a memory is composed of a set of fins which can be latched oppositely, and a hook member which can be used to clip the set of fins, wherein the aforementioned fins are hooked with a T-shape hook plate having horns and a T-shape slot having through-holes and a through-hole at its neck. The hook member is provided with perforations on its surfaces, and slant press pieces which are extended downward are located on surfaces of fins. After the fins are clipped by the hook member, the hook member is hooked with the slant press pieces through the shear sides below the perforations. In addition, lower edges of the aforementioned fins are provided with slant ribs extended outward, and by pressing the ribs, the aforementioned slant press pieces can be separated from the perforations of hook member.

### BACKGROUND OF THE INVENTION

(a) Field of the Invention

The present invention relates to a heat dissipating element for a memory, and more particularly to a heat dissipating element which is assembled at an exterior of memory, is not easily getting loose, and can be exchanged conveniently after being assembled.

(b) Description of the Prior Art

The heat dissipating problem for interior elements of a computer has always been an object to be solved and improved by related industries. In order to prevent an element such as a central processing unit (CPU), an integrated circuit (IC), a power transistor, and a memory from being overheated due to a long term of usage, thereby affecting its quality, a general method is to add a heat dissipating element onto an exterior of the element.

In terms of the heat dissipating element for a memory, two pieces of fins, along with two pieces of heat conducting plastic plates, were previously used to enclose the memory, followed by locking the fins with rivets. However, for a computer which is often moved, the fins are memory to be damaged due to a lack of efficient heat dissipation from a long term of usage, by using this kind of method of locking with the rivets.

In recent years, inventions related to a heat dissipating device for memory and its improvement, have been shown up in Taiwan Utility Patents 495101 and M261974. However, although the aforementioned two patents are an improvement to conventional drawbacks that the device cannot be latched quickly or cannot effectively prevent from a dust, they are still in lack of how to enable the heat dissipating device to be more solid without easily getting loose or to be quickly separated, after being assembled, which is a pity.

### SUMMARY OF THE INVENTION

Accordingly, the primary object of the present invention is to provide a heat dissipating element for a memory, which includes a set of fins that can be latched oppositely, and a hook member which enables the fins to be more solid after being latched, wherein the set of fins are latched by inserting a T-shape hook plate into a T-shape slot, thereby achieving a purpose that the fins will not easily get loose after being assembled.

Another object of the present invention is to provide a heat dissipating element for a memory, wherein shear sides of perforations on the hook member are formed by pressing slant press pieces located on the fins and extended downward, after clipping the fins with the hook member, such that the fins will not be shaken and loosened by an external force, after being assembled.

Still another object of the present invention is to provide a heat dissipating element for a memory, wherein ribs which are extended outward are located at lower edges of fins, such that the fins will be deformed adequately when the ribs are pressed, thereby facilitating the press pieces to be separated from the perforations.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a perspective view upon assembling the present invention.

FIG. 2 shows a perspective view of elements of the present invention.

FIG. 3 shows a schematic view upon hooking fins of the present invention.

FIG. 4 shows a cutaway view after assembling fins of the present invention.

FIG. 5 shows a cutaway view of assembling a fin and a hook member of the present invention.

FIG. 6 shows a schematic view of separating a fin from a hook member of the present invention.

### DETAILED DESCRIPTION OF THE PREFERRED EMBODIMENTS

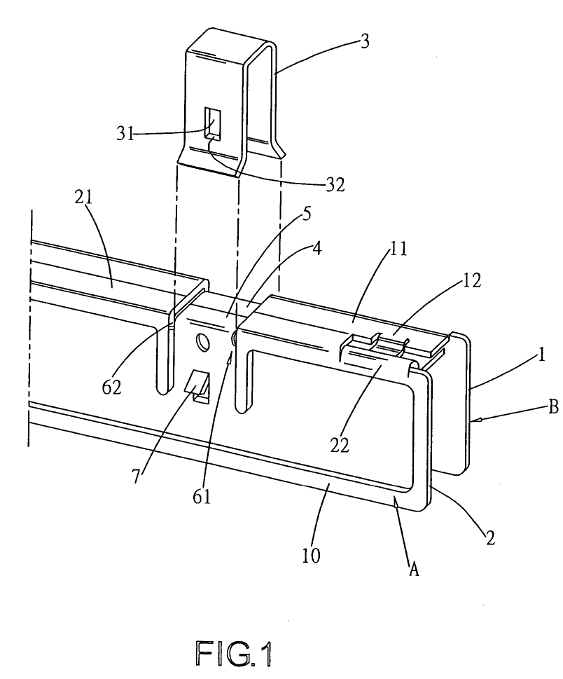

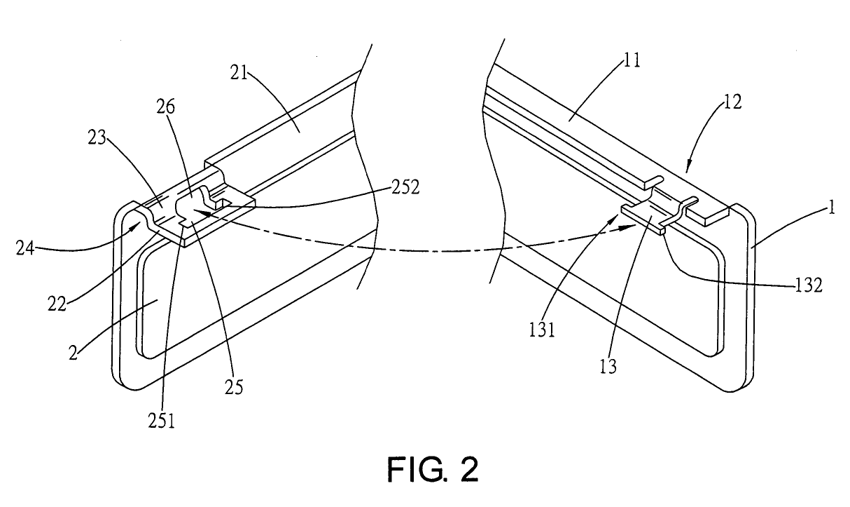

Referring to FIG. 1 and FIG. 2, a heat dissipating element of the present invention includes a set of fins 1, 2 which can be latched oppositely, and a hook member 3, wherein the fins 1, 2 are connected to a memory with heat conducting plates 10, and the top ends of fins 1, 2 are provided with connection plates 11, 21 which are bended toward each other. At two ends of connection plates 11, 21, insertion parts 12 and hook parts 22 are located at positions corresponding to each other. One end of the insertion part 12 is connected with the connection plate 11, and the other end is extended toward a front at a height slightly lower than that of the connection part 11. Horns 131, 132 are protruded at two sides of an end of insertion part 12 that is extended toward a front, thereby forming a T-shape hook plate 13. An end of the hook part 22 is connected with the connection plate 21 with an arc shape neck 23, such that an adequate space 24 is reserved between the neck 23 and the fin 2. A front end of the hook part 22 is also extended toward a front at a height slightly lower than that of the connection plate 21, and a horizontal surface of the hook part 22 is provided with a T-shape slot 25 whose two sides at its front end are provided with through-holes 251, 252 protruded outward. A rear end of T-shape slot 25 is connected with a through-hole 26 on the neck 23.

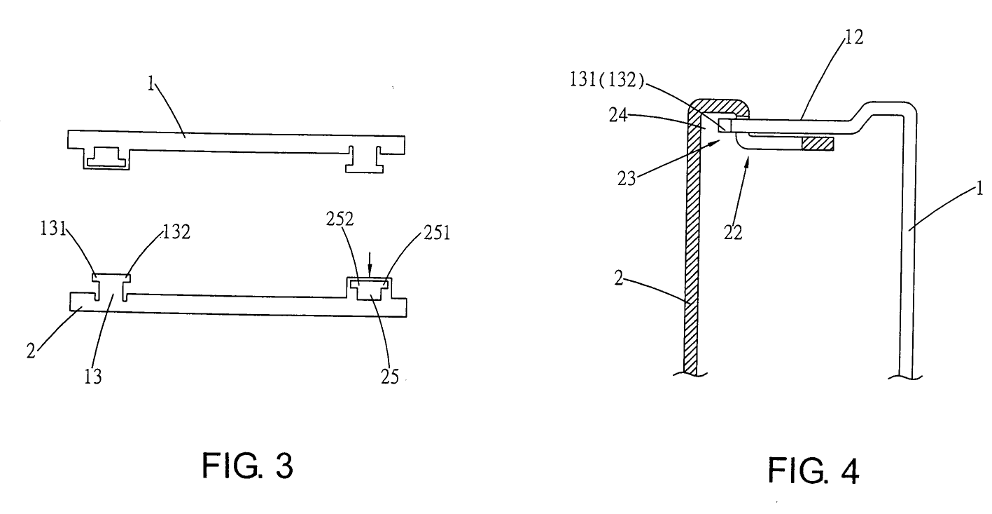

Referring to FIG. 3, when the fins 1, 2 are assembled oppositely, the horns 131, 132 of T-shape hook plate 13 are first passed through the through-holes 251, 252 of the T-shape slot 25, and then the whole T-shape hook plate 13 is passed through the T-shape slot 25 and turned by an angle, such that the horns 131, 132 of T-shape hook plate 13 will be moved to the rear space 24 (as shown in FIG. 4) of neck 23, to constitute an inverted hooking status of the T-shape hook plate 13, thereby accomplishing a connection of the insertion part 12 with the hook part 22.

Moreover, as shown in the drawings, the connection plates 11, 21 at top ends of the fins 1, 2 are provided with butted plates 4, 5 at central positions of the connection plates 11, 21, with heights slightly lower than those of the connection plates 11, 12. The heights of butted plates 4, 5 are slightly lower than those of the connection plates 11, 21, and their two sides are provided with indents 61, 62, to facilitate a correction of the fins 1, 2. The fins 1, 2 are located at lower ends of the connection plates 4, 5, and are provided with slant press pieces 7 which are vertical and extended downward.

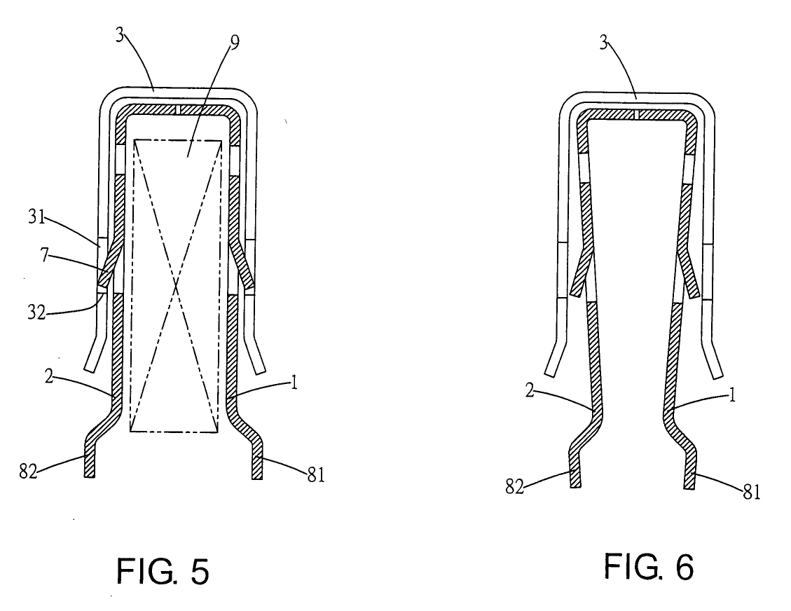

The aforementioned hook member 3 is a U-shape elastic body, whose surfaces are provided with perforations 31. After the memory is enclosed by the fins 1, 2, the hook member 3 is inserted into the butted plates 4, 5 of two fins 1, 2, such that the lower ends of press pieces 7 of fins 1, 2 are latched into the shear sides 32 of perforations (as shown in FIG. 5), thereby clipping and fixing the fins 1, 2.

Moreover, as shown in the drawings, the lower ends of fins 1, 2 are provided with ribs 81, 82 which are extended outward. Referring to FIG. 6, when the ribs 81, 82 are pressed, the fins 1, 2 are deformed properly, such that the press pieces 7 can be separated from the shear sides 32, so as to facilitate a separation of hook member 3 from the fins 1, 2.

Accordingly, by the T-shape hook plate with the horns and the T-shape device with the through-holes for horns and the through-hole at its neck, the fins can be assembled and hooked without easily getting loose by the shaking from external force. In addition, a stability of entire assembly can be enhanced by a hooking of the slant press pieces extended downward on the fins, and the shear sides of hook member; whereas the ribs on the fins further provide a convenient separation and exchanging to the hook member and the fins.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A heat dissipating element for a memory comprising a set of fins used to enclose the memory and a hook member used to clip the aforementioned fins, wherein top ends of fins are provided with connection plates, and an insertion part and a hook part are located at corresponding positions on the connection plate of fin, whereas surfaces of the hook part are provided with through-holes; one end of the aforementioned insertion part being provided with horns protruded outward, and one end of through-hole of the aforementioned hook part being provided with through-holes for passing through the horns, such that the horns will be away from the through-holes after hooking the insertion part and the hook part.

2. The heat dissipating element for a memory according to claim 1, wherein one end of the aforementioned hook part is connected with the connection plate with a neck, and a space is reserved between the neck and the fin; a through-hole being located on the neck for connecting with the through-holes of hook part; the horns being located at a rear space of the neck, after passing the insertion part through the through-holes of hook part.

3. The heat dissipating element for a memory according to claim 1, wherein the aforementioned fins are hooked to the hook member by shear sides formed below slant press pieces of fins and perforations of the hook member.

4. The heat dissipating element for a memory according to claim 2, wherein the aforementioned fins are hooked to the hook member by shear sides formed below slant press pieces of fins and perforations of the hook member.

5. The heat dissipating element for a memory according to claim 1, wherein one end of the aforementioned fin is provided with ribs which enable the fin to be deformed and separated from the hook member, after being pressed.

6. The heat dissipating element for a memory according to claim 2, wherein one end of the aforementioned fin is provided with ribs which enable the fin to be deformed and separated from the hook member, after being pressed.

7. The heat dissipating element for a memory according to claim 1, wherein the aforementioned fins are provided with butted plates at positions of hooking the hook member, and indentations are located two sides of the butted plates to serve as a correction function.

8. The heat dissipating element for a memory according to claim 2, wherein the aforementioned fins are provided with butted plates at positions of hooking the hook member, and indentations are located two sides of the butted plates to serve as a correction function.

9. The heat dissipating element for a memory according to claim 1, wherein the aforementioned fins are connected with an IC module of the memory with heat conduction plates.

10. The heat dissipating element for a memory according to claim 2, wherein the aforementioned fins are connected with an IC module of the memory with heat conduction plates.
